(19) United States
(12) Patent Application Publication
(10) Pub. No.: US 2025/0308580 A1
(43) Pub. Date: Oct. 2, 2025

(54) STACKED HYBRID MEMORY ARCHICTECTURE

(71) Applicant: Micron Technology, Inc., Boise, ID (US)

(72) Inventors: Wenlun Zhang, Tokyo (JP); Yuan He, Boise, ID (US)

(21) Appl. No.: 19/045,227

(22) Filed: Feb. 4, 2025

Related U.S. Application Data
(60) Provisional application No. 63/572,653, filed on Apr. 1, 2024.

(51) Int. Cl. G11C 11/412; G06F 5/01; G11C 11/4091; G11C 11/4096; G11C 11/419; H01L 25/16; H03K 19/20; H10B 80/00

(52) U.S. Cl. CPC G11C 11/412; G06F 5/01; G11C 11/4091; G11C 11/4096; G11C 11/419; H01L 25/16; H03K 19/20; H10B 80/00

(57) ABSTRACT

A stacked hybrid memory architecture includes a dynamic random-access memory (DRAM) device. The DRAM device stores a plurality of weights associated with an artificial neural network. The stacked hybrid memory architecture also includes a static random-access memory (SRAM) device bonded to the DRAM device. The SRAM device receives, from the DRAM device through a plurality of through silicon vias (TSVs), the plurality of weights associated with the artificial neural network. The SRAM device also performs a plurality of operations utilizing the plurality of weights. The stacked hybrid memory architecture also includes logic configured to perform a summation operation on a result of the plurality of operations.

### PRIORITY INFORMATION

This application claims the benefit of U.S. Provisional Application No. 63/572,653, filed on Apr. 1, 2024, the contents of which are incorporated herein by reference.

### TECHNICAL FIELD

The present disclosure relates generally to semiconductor memory and methods and, more particularly, to apparatuses and methods associated with a stacked hybrid memory architecture.

### BACKGROUND

A memory system can include one or more memory devices that store data. The memory devices can be, for example, non-volatile memory devices and volatile memory devices. The memory system can include one or more analog and/or digital circuits to facilitate operation of the memory system. In general, a host system can utilize a memory system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory system in accordance with some embodiments of the present disclosure.

FIG. 2 illustrates an example of a hybrid memory device in accordance with some embodiments of the present disclosure.

FIG. 3A illustrates an example of a static random-access memory device in accordance with some embodiments of the present disclosure.

FIG. 3B illustrates an example of a dynamic random-access memory device in accordance with some embodiments of the present disclosure.

FIG. 4 illustrates an example of a processing element of a static random-access memory device in accordance with some embodiments of the present disclosure.

FIG. 5 is a flow diagram corresponding to a method for implementing a hybrid memory device in accordance with some embodiments of the present disclosure.

FIG. 6 is a block diagram of an example computer system in which embodiments of the present disclosure may operate.

### DETAILED DESCRIPTION

Aspects of the present disclosure are directed to implementing a hybrid memory architecture that can be useful for artificial neural networks. A hybrid memory architecture, which may be referred to herein as a hybrid memory device, can include two or more types of memory devices that are bonded (e.g., in a stacked configuration). For example, a hybrid memory device can include a static random-access memory (SRAM) device and a dynamic random-access memory (DRAM) device that are bonded. The hybrid memory device can be utilized to implement an artificial neural network (ANN) such as a convolution neural network (CNN). For example, a DRAM device can store a plurality of weights associated with an artificial neural network. The SRAM device that is bonded to the DRAM device can receive, from the DRAM device through a plurality of through silicon vias (TSVs), the plurality of weights associated with the artificial neural network. The SRAM device can perform a plurality of operations utilizing the plurality of weights. The hybrid memory device can also include logic configured to perform a summation operation on a result of the plurality of operations to implement the ANN.

As used herein, ANNs including CNNs can provide learning by forming probability weight associations between an input and an output. The probability weight associations can be provided by a plurality of nodes that comprise the ANN. The nodes together with weights, biases, and activation functions can be used to generate an output of the ANN based on the input to the ANN. A plurality of nodes of the ANN can be grouped to form layers of the ANN.

As used herein, AI refers to the ability to improve an apparatus through “learning” such as by storing patterns and/or examples which can be utilized to take actions at a later time. Deep learning refers to a device's ability to learn from data provided as examples. Deep learning can be a subset of AI. Neural networks, among other types of networks, can be classified as deep learning. Improving the efficiency at which ANNs, including CNNs, are executed can improve a function of a memory device executing the ANN and the function of the device in which the memory device is implemented. For example, improving the latency, power consumption, and/or throughput of the memory device implementing the CNN can cause an improvement to the latency, power consumption, and/or throughput of a memory system.

Deep neural networks (DNN) can be used in machine learning tasks such as image classification, speech recognition, and/or anomaly detection, among other types of machine learning tasks. DNNs can include CNNs. Implementing CNN may be energy inefficient given that weights utilized by the CNN may be reused multiple times to perform operations to implement the CNN. The reuse of weights for CNN can include reading the same weights multiple times from memory prior to using the weights to perform operations. Inefficient weight reuse for CNN can contribute to the energy efficiency for implementing CNNs. However, reading a weight from DRAM may not allow for the weights to be reused without the memory cells that store the weight being refreshed. The constant refreshing of memory cells as the weights are read and re-read can be inefficient for energy consumption. SRAM could be used to store weights. However, utilizing SRAM to store weights can limit the space available to store weights and/or data utilized by CNNs as compared to DRAM.

In order to address these and other deficiencies of current approaches, embodiments of the present disclosure allow the implementation of a hybrid memory device to allow for the reading of memory cells that store weights to be performed multiple times without requiring that the memory cells be refreshed and allows for the storage capacity of DRAM. In various examples, a hybrid memory device can be a hybrid compute-in-memory (CIM) device that stacks a DRAM device and an SRAM device for multi-bit DNN computations. The hybrid memory device can combine the advantages of both DRAM devices and SRAM devices in a CIM system. The hybrid memory device can be utilized for efficient execution CNNs and can generally be compatible with different types of ANNs and/or machine learning algorithms.

A hybrid memory device including an SRAM device bonded to a DRAM device can include high memory density, high throughput, and high energy efficiency for CNN implementation as compared to implanting a CNN using an SRAM device or a DRAM device separately. A hybrid memory device can be used to implement a CNN using INT8, INT16, or INT 32 DNN architectures. The stacked DRAM device and SRAM device CIM system with multi-bit AND multiply-and-accumulate (MAC) compute components can be implemented to reduces power dissipation of data transition in deep learning computing systems. The hybrid memory device can have a high dimension parallel filter computation with weight reuse scheme, entailing both high throughput and energy efficiency as compared to using an SRAM device or a DRAM device.

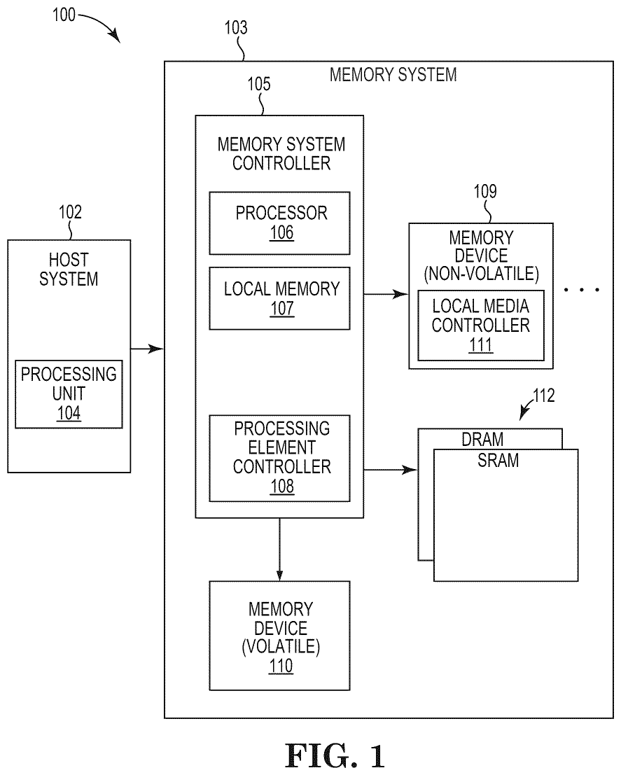

FIG. 1 illustrates an example computing system 100 that includes a memory system 103 in accordance with some embodiments of the present disclosure. The memory system 103 can include media, such as one or more volatile memory devices (e.g., memory device 110), one or more non-volatile memory devices (e.g., memory device 109), or a combination of such.

A memory system 103 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

In other embodiments, the computing system 100 can be deployed on, or otherwise included in a computing device such as a desktop computer, laptop computer, server, network server, mobile computing device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor can include a display screen that is between approximately 5.2 inches and 7 inches (measured diagonally). Examples of “mobile computing devices” are not so limited, however, and in some embodiments, a “mobile computing device” can refer to an IoT device, among other types of edge computing devices.

The computing system 100 can include a host system 102 that is coupled to one or more memory systems 103. In some embodiments, the host system 102 is coupled to different types of memory system 103. FIG. 1 illustrates one example of a host system 102 coupled to one memory system 103. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 102 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 102 uses the memory system 103, for example, to write data to the memory system 103 and read data from the memory system 103.

The host system 102 includes a processing unit 104. The processing unit 104 can be a central processing unit (CPU) that is configured to execute an operating system.

The host system 102 can be coupled to the memory system 103 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), Compute Express Link (CXL), or any other interface. The physical host interface can be used to transmit data between the host system 102 and the memory system 103. The host system 102 can further utilize an NVM Express (NVMe) interface to access components (e.g., memory devices 109) when the memory system 103 is coupled with the host system 102 by the PCIe interface. The physical host interface can provide an interface for passing control, address, data, and other signals between the memory system 103 and the host system 102. FIG. 1 illustrates a memory system 103 as an example. In general, the host system 102 can access multiple memory systems via the same communication connection, multiple separate communication connections, and/or a combination of communication connections.

The memory devices 109, 110 can include any combination of the different types of non-volatile memory devices and/or volatile memory devices. The volatile memory devices (e.g., memory device 110) can be, but are not limited to, random access memory (RAM), such as dynamic random-access memory (DRAM) and synchronous dynamic random-access memory (SDRAM).

Some examples of non-volatile memory devices (e.g., memory device 109) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 109, 110 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 109 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 109 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 109 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory system controller 105 (or controller 105 for simplicity) can communicate with the memory devices 109 to perform operations such as reading data, writing data, or erasing data at the memory devices 109 and other such operations. The memory system controller 105 can include hardware such as one or more integrated circuits and/or discrete components, a buffer memory, or a combination thereof. The hardware can include digital circuitry with dedicated (i.e., hard-coded) logic to perform the operations described herein. The memory system controller 105 can be a microcontroller, special purpose logic circuitry (e.g., a field programmable gate array (FPGA), an application specific integrated circuit (ASIC), etc.), or another suitable processor.

The memory system controller 105 can include a processor 106 (e.g., a processing device) configured to execute instructions stored in a local memory 107. In the illustrated example, the local memory 107 of the memory system controller 105 includes an embedded memory configured to store instructions for performing various processes, operations, logic flows, and routines that control operation of the memory system 103, including handling communications between the memory system 103 and the host system 102.

In some embodiments, the local memory 107 can include memory registers storing memory pointers, fetched data, etc. The local memory 107 can also include read-only memory (ROM) for storing micro-code. While the example memory system 103 in FIG. 1 has been illustrated as including the memory system controller 105, in another embodiment of the present disclosure, a memory system 103 does not include a memory system controller 105, and can instead rely upon external control (e.g., provided by an external host, or by a processor or controller separate from the memory system).

In general, the memory system controller 105 can receive commands or operations from the host system 102 and can convert the commands or operations into instructions or appropriate commands to achieve the desired access to the memory device 109 and/or the memory device 110. The memory system controller 105 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 109. The memory system controller 105 can further include host interface circuitry to communicate with the host system 102 via the physical host interface. The host interface circuitry can convert the commands received from the host system into command instructions to access the memory device 109 and/or the memory device 110 as well as convert responses associated with the memory device 109 and/or the memory device 110 into information for the host system 102.

The memory system 103 can also include additional circuitry or components that are not illustrated. In some embodiments, the memory system 103 can include a cache or buffer (e.g., DRAM) and address circuitry (e.g., a row decoder and a column decoder) that can receive an address from the memory system controller 105 and decode the address to access the memory device 109 and/or the memory device 110.

In some embodiments, the memory device 109 includes local media controllers 111 that operate in conjunction with memory system controller 105 to execute operations on one or more memory cells of the memory devices 109. An external controller (e.g., memory system controller 105) can externally manage the memory device 109 (e.g., perform media management operations on the memory device 109). In some embodiments, a memory device 109 is a managed memory device, which is a raw memory device combined with a local controller (e.g., local controller 111) for media management within the same memory device package. An example of a managed memory device is a managed NAND (MNAND) device.

The memory system 103 can include processing element controller 108. Although not shown in FIG. 1 so as to not obfuscate the drawings, the processing element controller 108 can include various circuitry to facilitate aspects of the disclosure described herein. In some embodiments, the processing element controller 108 can include special purpose circuitry in the form of an ASIC, FPGA, state machine, hardware processing device, and/or other logic circuitry that can allow the processing element controller 108 to control processing elements of the hybrid memory device 112.

In some embodiments, the memory system controller 105 includes at least a portion of the processing element controller 108. For example, the memory system controller 105 can include a processor 106 (processing device) configured to execute instructions stored in local memory 107 for performing the operations described herein. In some embodiments, the processing element controller 108 is part of the host system 103, an application, or an operating system. The processing element controller 108 can be resident on the memory system 103 and/or the memory system controller 105. As used herein, the term “resident on” refers to something that is physically located on a particular component. For example, the processing element controller 108 being “resident on” the memory system 103 refers to a condition in which the hardware circuitry that comprises the processing element controller 108 is physically located on the memory system 103. The term “resident on” may be used interchangeably with other terms such as “deployed on” or “located on,” herein.

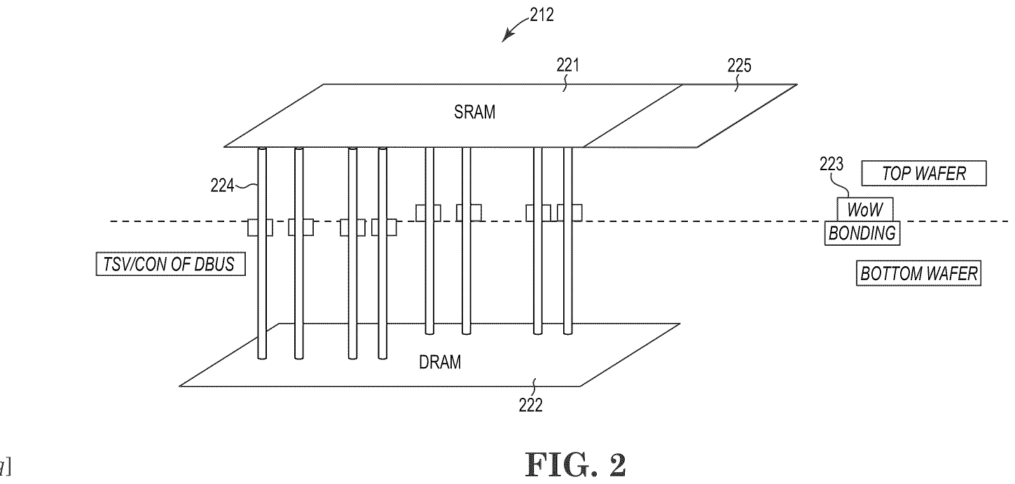

The hybrid device 112 can include a DRAM device and an SRAM device. The DRAM device and the SRAM device can be bonded as described further in FIG. 2. In various examples, The DRAM device and the SRAM device can provide data to each other utilizing TSVs. The DRAM device and the SRAM device can be described as being stacked given that the DRAM device and the SRAM device are bonded.

The SRAM device can include a plurality of processing elements (PEs). The PEs of the SRAM device can comprise one or more memory cells configured to store data. The SRAM device can also include logical gates that can receive the data stored in the SRAM device and data stored in the DRAM device simultaneously. The logical gates can perform operation on the data received from the SRAM device and the DRAM device. The processing element controller 108 can manage the movement of data from the DRAM device to the SRAM device and/or from the SRAM device to the DRAM device. For example, the processing element controller 108 can cause data to be read from the DRAM device, can cause the data to be moved to the SRAM device, and can cause the data to be stored in the SRAM device. In various examples, the SRAM device may not include sensing circuitry while the DRAM device includes sensing circuitry. The processing element controller 108 can also control processing elements of the hybrid device 112 to cause operations to be performed on the data moved from the DRAM device to the SRAM device.

The data stored in the SRAM device can be weights of a CNN. The weights can initially be stored in the DRAM device. The weights can be read from the DRAM device and provided to the SRAM device. The SRAM device can store the weights in the memory cells of the PEs. The SRAM device can utilize the weights and data stored in the DRAM device to perform a plurality of operations utilized to implement a CNN. Although a single hybrid memory device 112 is shown, multiple hybrid memory devices can be implemented in the memory system 103.

FIG. 2 illustrates an example of a hybrid memory device 212 in accordance with some embodiments of the present disclosure. The hybrid memory device 212 can be a device, such as device 112 in FIG. 1, and can include an SRAM device 221 and a DRAM device 222. The hybrid memory device 212 also includes shift accumulate circuitry 225.

The hybrid memory device 212 can be a three-dimensional (3D) integrated circuit (IC). The 3D IC can be a metal-oxide semiconductor (MOS) IC manufactured by stacking semiconductor wafers or dies and interconnecting them vertically using, for example, through-silicon vias (TSVs) or metal connections, to function as a single device to achieve performance improvements at reduced power and smaller footprint than conventional two-dimensional processes.

The SRAM device 221 can be bonded to the DRAM device 222. For example, the SRAM device 221 and the DRAM device 222 can be bonded via a wafer-on-wafer bond 223. The SRAM device 221 can be a first wafer and the DRAM device 222 can be a second wafer that are bonded using the wafer-on-wafer bond 223.

After fabrication of the electronic devices (e.g., the SRAM device 221 and the DRAM device 222) on a first wafer and a second wafer, the first wafer and the second wafer can be diced (e.g., by a rotating saw blade cutting along streets of the first wafer and the second wafer). However, according to at least one embodiment of the present disclosure, after fabrication of the devices on the first wafer and the second wafer, and prior to dicing, the first wafer and the second wafer can be bonded together by a wafer-on-wafer (WoW) bonding process. Subsequent to the wafer-on-wafer bonding process, the dies (e.g., the SRAM device and the DRAM device) can be singulated. For example, the SRAM wafer can be bonded to the DRAM wafer in a face-to-face orientation meaning that their respective substrates (wafers) are both distal to the bond while the SRAM dies and the DRAM dies are proximal to the bond 223. This enables individual SRAM die and DRAM die to be singulated together as a single package after the SRAM wafer and the DRAM wafer are bonded together. The bond 223 can be formed by a low temperature (e.g., room temperature) bonding process. In some embodiments, the bond 223 can be further processed with an annealing step (e.g., at 300 degrees Celsius).

In various examples, the SRAM device 221 can be a top wafer and the DRAM device 222 can be a bottom wafer. However, “top” and “bottom” are not intended to describe an absolute orientation but rather are intended to describe an orientation relative to each other (e.g., the SRAM device 221 and the DRAM device 222). In various examples, the DRAM device 222 can be the top wafer and the SRAM device 221 is the bottom wafer.

The TSVs 224 can be used for communication of data between or through stacked memory die. For example, the TSVs 224 can provide signals between the DRAM device 222 and the SRAM device 221. For instance, parameters (e.g., weights, biases, and/or activation functions, among others) of a CNN can be stored in the DRAM device 222 and can be provided to the SRAM device 221 through the TSVs 224. In various instances, the parameters can be updated in the SRAM device 221. The updated parameters can be provided from the SRAM device 221 to the DRAM device 222 via the TSVs 224. The updated parameters can be stored in the DRAM device 222.

In various instances, the parameters provided from the DRAM device 222 to the SRAM device 221 can be stored in the SRAM device 221. The parameters can be utilized to process an input to the CNN. For example, the input to the CNN can also be provided from the DRAM device 222 to the SRAM device 221 via the TSVs 224. Forward propagation signals from hidden layers of the CNN can also be processed utilizing the parameters. The forward propagation signals can also be provided from the DRAM device 222 to the SRAM device 221 via the TSVs 224.

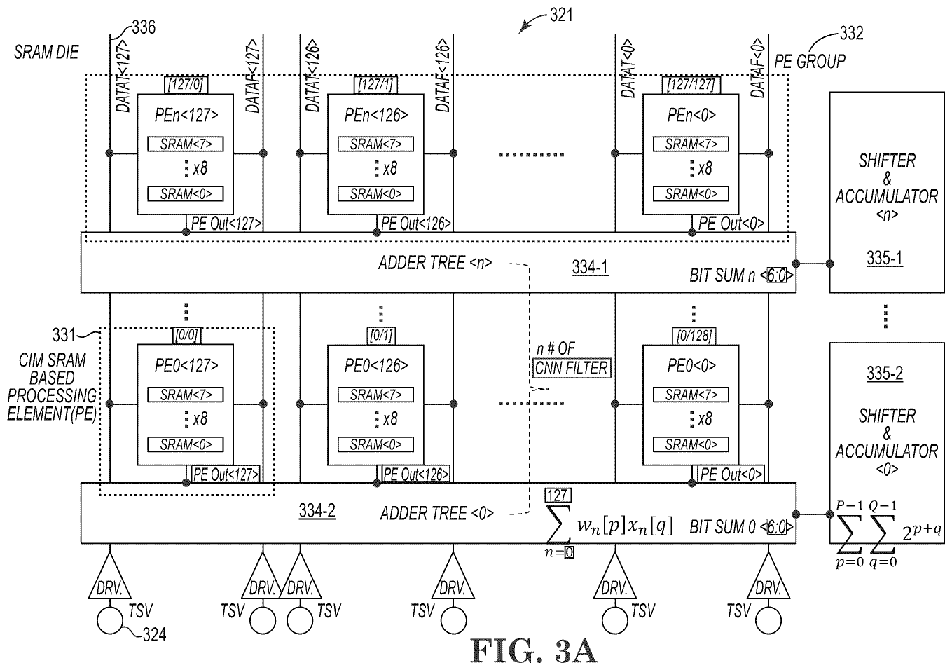

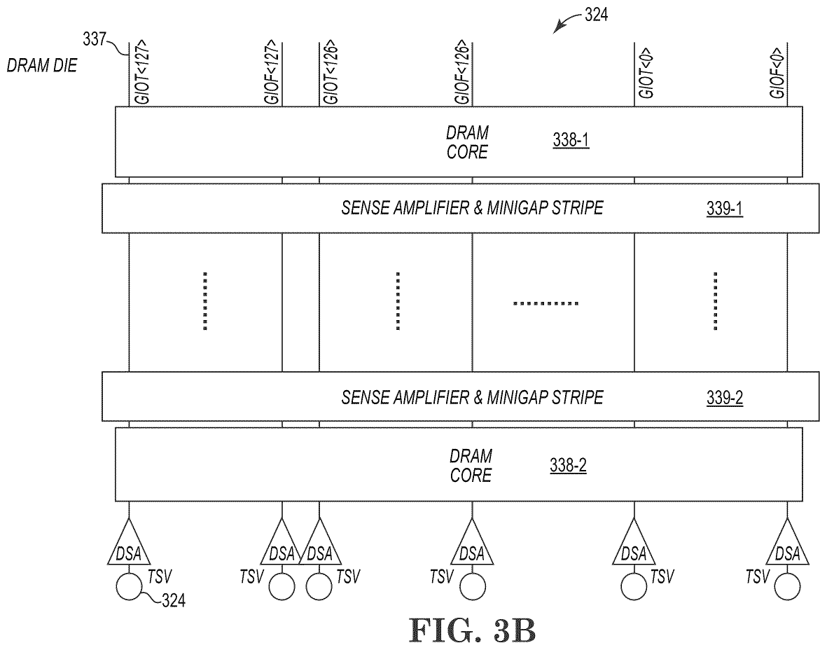

The SRAM device 221 can include processing elements (PE) and the shift and accumulate circuitry 225 which can be utilized to perform operations utilizing the parameters of the CNN and the input signals and/or the forward propagation signals. The shift and accumulate circuitry 225 can be hardware and/or firmware. The shift and accumulate circuitry 225 can perform operations to shift input data and to accumulate a plurality of outputs of the shift and accumulate circuitry 225 as described below. FIG. 3A shows the SRAM device 221 (e.g., the SRAM die) while FIG. 3B shows the DRAM device 222 (e.g., the DRAM die).

FIG. 3A illustrates an example of an SRAM device 321 in accordance with some embodiments of the present disclosure. The SRAM device 321 can include PEs 331 and groups 332 of PEs. The SRAM device 321 can also include logic (e.g., Adder Tree) 334-1, 334-2 and shift and accumulate circuitry 335-1, 335-2. The SRAM device 321 can also include TSVs 324 that couple the SRAM device 321 to the DRAM device 324 of FIG. 3B.

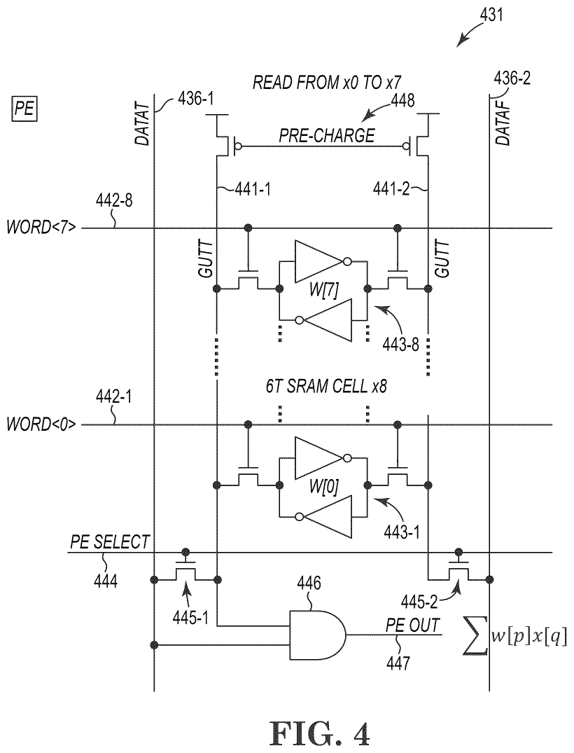

Each of the PEs 331 can include a number of memory cells (e.g., SRAM<0>, . . . , SRAM<7>). For example, each of the PEs 331 can include eight memory cells. Each of the PEs 331 can also include logic (not shown) for performing logical operations. The logic for performing logical operations is shown in FIG. 4 as logic circuitry 446.

Each of the PEs 331 can be coupled to data lines 336 of the SRAM device 321. For example, each of the PEs 331 can be coupled to complementary data lines 336 (e.g., DATAT, DATAF). The complementary data lines 336 can also be coupled to the TSVs 324. Such that data provided by the TSVs 324 can be stored in the memory cells of the PEs 331. The TSVs 324 can couple the SRAM device 321 to the DRAM device 322 such that the DRAM device 322 can provide data to the SRAM device 321 via the TSVs 324. The TSVs 324 can provide the data received from the DRAM device 322 to the data lines 336. The data lines 336 can provide the data to the PEs 331. The PEs 331 can store the data in the memory cells of the PEs 331.

In various instances, the PEs 331 can perform operations using the data stored in the memory cells and separate data provided by the TSVs 324. The TSVs 324 can provide first data at a first time and second data at a second time. The first data can be stored in the PEs 331. The second data may not be stored in the PEs 331 but may be used by the PEs 331 to perform operations in conjunction with the use of the first data.

The logic 334-1, 334-2 can receive the results of the operations performed by the PEs 331. The logic 334-1, 334-2 can perform a plurality of additional operations using the results of the operations performed by the PEs. For example, the logic 334-1, 334-2 can perform summation operations. The logic 334-1, 334-2 can sum a quantity of bits of the results of the operations performed by the PEs 331. For example, the logic 334-1, 334-2 can sum “1” bits of the results of the operations performed by the PEs 331. The logic 334-1, 334-2 can sum “0” bits of the results of the operations performed by the PEs 331.

Each of the logic 334-1, 334-2 can be coupled to a different PE group 332. For example, the logic 334-1 can be coupled to a first PE group while the logic 334-2 is coupled to a second PE group. The shift and accumulate circuitry 335 can perform additional operations on the outputs of the logic 334-1, 334-2. For example, the shift and accumulate circuitry 335-1 can be coupled to the logic 334-1 and can perform operations on the output of the logic 334-1. The shift and accumulate circuitry 335-2 can be coupled to the logic 334-1 and can perform operations on the output of the logic 334-2.

In various examples, the PEs 331, the logic 334-1. 334-2, and the shift and accumulate circuitry 335-1, 335-2 can perform operations to implement a CNN. For example, a convolution layer of the CNN can include performing a sliding dot product. In a sliding dot product, a filter can stride along the input feature map and can take the dot product between them. In various examples, the filter weights can be reused throughout striding the whole input feature map. The filter weights can be reused because the filter weights can be stored in the memory cells of the PEs 331.

A sliding dot product can be used to implement a multi-bit bit-serial MAC computation which is expresses as:

$$0 = {\sum }_{n = 0}^{N - 1} {w}_{n} {x}_{n} = {\sum }_{p = 0}^{P - 1} {\sum }_{q = 0}^{Q - 1} {2}^{p + q} {\sum }_{n = 0}^{N - 1} {w}_{n} [ p ] {x}_{n} [ q ] .$$

The expression wₙ[p]xₙ[q] can be performed using the PEs 331. The expression Σₙ₌₀^{N-1} can be performed by the logic 334-1, 334-2. The expression Σₚ₌₀^{P-1}Σ_{q=0}^{Q-1}2^{p+q} is performed by the shift and accumulate circuitry 335-1, 335-2. The data wₙ[p] can be stored in the memory cells of the PEs 331 while xₙ[q] is provided by the TSVs 324 without being stored in the memory cells of the PEs 331. In various instances, the data xₙ[q] can be stored in the memory cells of the PEs 331 while wₙ[p] is provided by the TSVs 324.

In various examples, 128 PEs 331 are placed between complementary data lines (DATAT and DATAF). Each PE group 332 can consist of a CNN filter which can be utilized to implement convolution neural networks. Each of the PE groups can implement parallel computations simultaneously. Performing operations in parallel using the PE groups 332 can improve throughput of the SRAM device 321. The complementary data lines 336 (e.g., DATAT, DATAF) can be on a same pitch with the complementary global input output (GIO) lines 337 of FIG. 3B.

FIG. 3B illustrates an example of a DRAM device 324 in accordance with some embodiments of the present disclosure. The DRAM device 324 includes complementary GIO lines 337, DRAM cores 338-1, 338-2, sense amplifiers 339-1, 339-2, and TSVs 324.

The TSVs 324 of FIG. 3B can be coupled to or can be the TSVs 324 of FIG. 3A. In various examples, TSVs 324 of FIG. 3B can be coupled to the TSVs 324 of FIG. 3A.

The DRAM cores 338-1, 338-2 can include memory cells. The memory cells can store data that can be utilized by the PEs 331 of FIG. 3A to perform operations. For example, the DRAM cores 338-1, 338-2 can store weights and inputs. The DRAM cores 338-1, 338-2 can be read using the sense amplifiers 339-1, 339-2 to retrieve a plurality of weights. The weights can be provided to the SRAM device 321 utilizing the TSVs 324. After providing the weights, the DRAM cores 338-1, 338-2 can be read to retrieve inputs stored in the DRAM cores 338-1, 338-2. The read inputs can be provided to the SRAM device 321 utilizing the TSVs 324. The SRAM device 321 can utilize the weights and the inputs to perform a plurality of operations as described above.

FIG. 4 illustrates an example of a PE 431 of an SRAM device in accordance with some embodiments of the present disclosure. The PE 431 can include pre-charge circuitry 448, memory cells 443-1, . . . , 443-8, and logic circuitry 446. The memory cells 443-1, . . . , 443-8 can also be referred to as memory cells 443. The PE 431 can be coupled to complementary data lines 436-1, 436-2. The memory cells 443 can be coupled to complementary GUT lines (e.g., GUTT, GUTF) 441-1, 441-2, referred to as GUT lines 441, and word lines 442-1, . . . , 442-8. The GUT lines 441 can act as “local digit lines”. The data lines 436 act as “global digit lines”. In various examples, the memory cells 443 can be 6T memory cells. The memory cells 443 can be implemented as a different type of memory cell and are not limited to 6T memory cells.

The PE 431 can also include select circuitry 445-1, 445-2, referred to as select circuitry 445. The select circuitry 445 can be coupled to a select line 444 that can be used to couple the data lines 436 to the GUT lines 441. For instance, a first data value can be read from a DRAM device. The first data value can be provided from the DRAM device to the SRAM device via TSVs. The TSVs can provide the first data value to the data lines 436. The select lines 444 may be activated to activate the select circuitry 445 to cause the first data value to be provided to the GUT lines 441 from the data lines 436. The select circuitry 445 can couple the data lines 436 to the GUT lines 441. The GUT lines 441 can provide the data value to the memory cells 443. The memory cells can store the GUT lines 441.

A second data value can be read from the DRAM device. The second data value can be provided from the DRAM device to the SRAM device via the TSVs. The TSVs can provide the second data value to the data lines 436. Signals can be provided to through the select lines 444 to cause the select circuitry 445 to remain inactive such that the second data value is provided to the logic circuitry 446 and not the GUT lines 441. The pre-charge circuitry 448 can also cause the memory cells 443 to be read such that the first data value is provided through the GUT lines 441 to the logic circuitry 446. The logic circuitry 446 can perform an operation using the first data value read from the memory cells 443 and the second data value provided by the data lines 436.

The logic circuitry 446 can be implemented as an AND gate. The AND gate can perform the operation wₙ[p]xₙ[q]. The output 447 of the AND gate can be the output of the PE 431. The output 447 of the PE 431 can be provided to the logic (Adder Tree). Given that the output 447 of the PE 431 is not provided through a global I/O. The output 447 of the PE 431 is not provided to a sense amplifier. The output of the PE 431 is not amplified. The inputs to the logic circuitry 446 are also not amplified by sense amplifiers of the SRAM device given that the SRAM device can be implemented without sense amplifiers. Storing the first data value in the memory cells 443 can allow the first data value to be reused multiple times without refreshing the memory cells 443 to allow for a more efficient use of power as compared to refreshing the first data value in memory cells each time the first data value is read from the memory cells.

The second value can be a single bit while the first value can be multiple bits. For example, x₀ can be the second value while w₀ is the first bit of the first value. The operations w₀x₀, w₁x₀, . . . , w₇x₀ are performed prior to receipt of a different input value from the DRAM device x₁. The weights (first value) can be reused to perform the operations w₀x₁, w₁x₁, . . . , w₇x₁. The same process can be repeated until the operations w₀x₇, w₁x₇, . . . , w₇x₇. are performed.

The processing element controller of the SRAM device and/or of the memory system can control the data lines 436, the GUT lines 441, the word lines 442, the select line 444, the pre-charge circuitry 448, and/or the select circuitry 445. While the function of a single PE 431 is described in FIG. 4, the processing element controller can control multiple PEs to perform multiple operations (AND operations) at relatively the same time.

A DRAM device has the advantage of high cell density as compared to an SRAM device, but does not support weight reuse because the cell data is destructive. Once the cell data is read out through charge sharing, the cell cap is written back through digit lines. The same weight data is accessed repeatedly during the whole CONV (convolution) computation, which deteriorates the throughput and the energy efficiency. The SRAM device uses latches as memory cells. The storage node is non-destructive and can be accessed while performing computation, entailing weight reuse with high throughput and energy efficiency. However, the SRAM cell density is low as compared to the DRAM device and is not capable to store large quantities of data as compared to the DRAM device during the deep learning computation cycle. The power dissipation of data transition between SRAM macro and system RAM (DRAM) occupies most of the power in the system, which becomes the bottleneck for practical use of SRAM-based CIM system. The examples described herein integrate the advantages of both DRAM devices and SRAM devices to realize a CIM solution with both high cell density that supports weight reuse.

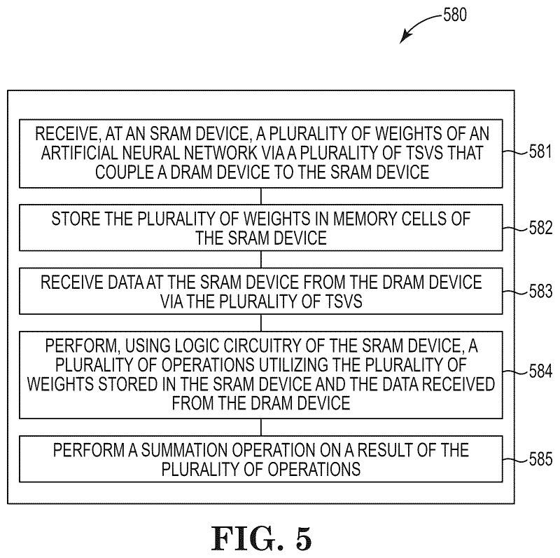

FIG. 5 is a flow diagram corresponding to a method 580 for implementing a hybrid memory device in accordance with some embodiments of the present disclosure. The method 580 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 580 is performed by the processing element controller 108 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 580 includes performing operations using a hybrid memory device. As described above, the operations can be performed utilizing a hybrid memory device that includes a DRAM device and an SRAM device.

At operation 581, a DRAM device can store a plurality of weights associated with an ANN. The ANN can be a CNN. At operation 582, an SRAM device that is bonded to the DRAM device can receive from the DRAM device through a plurality of through silicon vias (TSVs) the plurality of weights associated with the artificial neural network. The weights can correspond to the CNN. For examples, the weights can be used to provide signals from one layer of the CNN to a different layer of the CNN. At operation 583, The SRAM device can perform a plurality of operations utilizing the plurality of weights. The plurality of operations can also be performed utilizing inputs provided by the DRAM device. At operation 584, logic of the SRAM device can perform a summation operation on a result of the plurality of operations.

The TSVs can couple global input output (GIO) lines of the DRAM device to data lines of the SRAM device. For example, the TSVs of the DRAM device can be coupled to the GIO lines of the DRAM device. The TSVs of the SRAM can be coupled to the TSVs of the DRAM device and to the data lines of the SRAM device. The TSVs allow for data to be provided from the DRAM device to the SRAM device.

The SRAM device can perform the plurality of operations utilizing a number of logic gates. For example, each PE of the SRAM device can include an AND gate that can perform AND operations. Although an AND operation is described herein, different types of logical gates can be implemented in various configurations to perform one or more operations on the data stored in the memory cells of the SRAM device and the data provided by the DRAM device. For example, the SRAM device can perform the plurality of operations utilizing the plurality of weights and data stored in the DRAM device.

The weights and the data can be provided from the DRAM device to the SRAM device via the TSVs. The weights and the data can be provided to the SRAM device at different times. For example, the weights can be provided to the SRAM device at a first time while the data is provided at a time that the operations are performed by the SRAM device. Both the weights and the data can be provided to the SRAM device utilizing the same TSVs or different TSVs.

The SRAM device can perform the plurality of operations without a use of the sensing circuitry. The SRAM device may not include sensing circuitry. For example, the weights can be read from the memory cells of the SRAM device without the use of sensing circuitry. The weights can be provided to the AND gate without the use of sensing circuitry.

In various examples, a plurality of weights of an ANN can be received at a SRAM device via a plurality of TSVs that couple a DRAM device to the SRAM device. The plurality of weights can correspond to an CNN. The plurality of weights in memory cells of the SRAM device can be stored in the SRAM device. Data (e.g., additional data) can be received at the SRAM device from the DRAM device via the plurality of TSVs. Logic circuitry of the SRAM device can perform a plurality of operations utilizing the plurality of weights stored in the SRAM device and the data received from the DRAM device. A summation operation (e.g., Adder Tree) can be perform on a result of the plurality of operations. The summation operation can sum a quantity of bits of the result. For example, the summation operation can sum the “1” bits of the result or the “0” bits of the result. The summation operation can sum bit patters of the results, among other characteristics of the result that can be summed.

The data can be read from the DRAM device. The data can be read using sensing circuitry which is different than data read from the SRAM device which is performed without the use of sensing circuitry. The data read from the DRAM device can be broadcast to the SRAM device utilizing data lines of the SRAM device. For example, the DRAM device can have transceivers coupled to the global lines of the DRAM device and the TSVs to cause the data to be broadcast to the SRAM device.

In various examples, the plurality of weights can be stored in the memory cells of the SRAM device by firing a plurality of select lines and word lines to cause the plurality of weights to be transferred from the data lines to memory cells of the SRAM device. For example, the plurality of select lines can couple data lines of the SRAM device to GUT lines of the SRAM device. The plurality of weights can be transferred from the data lines to the GUT lines and from the GUT lines to the memory cells of the SRAM device. The weights can be stored in the memory cells of the SRAM device. Each of the memory cells of the PE can be updated individually. For example, Each of the word lines can be fired sequentially along with the PE select line to cause corresponding memory cells to be updated sequentially.

In various examples, the plurality of weights can be updated once stored in the SRAM device. The plurality of weights can be updated by firing a plurality of select lines of the SRAM device to transfer the plurality of weights from the data lines to the memory cells of the SRAM device.

In various examples, a DRAM device can store data. A SRAM device can store a plurality of weights of an ANN. The SRAM device can be bonded to the DRAM device. The SRAM device can receive the data via a plurality of TSVs that couple the DRAM device to the SRAM device. The SRAM device can perform a first plurality of operations utilizing the plurality of weights stored in the SRAM device and the data received from the DRAM device. Logic of the SRAM device can perform a summation operation on a result of the first plurality of operations. Shift and accumulate circuitry of the SRAM device can perform a second plurality of operations using a result of the summation operation. The first plurality of operations, the summation operation, and the second plurality of operations are performed to implement an ANN. For example, the shift and accumulate circuitry can perform the second plurality of operations to implement a CNN.

The SRAM device can include a plurality of processing elements, wherein each of the plurality of processing element includes a plurality of memory cells configured to store one of the plurality of weights. Each of the processing elements can include select circuitry configured to couple the data lines of the SRAM device to GUT lines of the SRAM device to cause the plurality of weights to be stored in the plurality of process elements. For example, the plurality of weights can be stored in memory cells of the plurality of processing elements. The plurality of memory cells can be directly coupled to the GUT lines and indirectly coupled to the data lines via the select circuitry. The SRAM device can perform the first plurality of operations by concurrently transferring the plurality of weights via the GUT lines and the data via the data lines to AND gates of the plurality of processing elements.

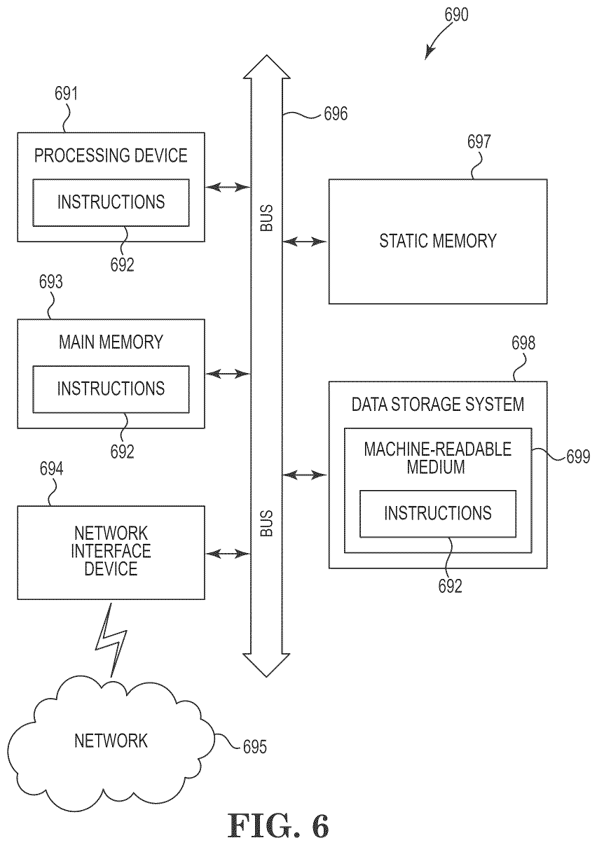

FIG. 6 is a block diagram of an example computer system in which embodiments of the present disclosure may operate. For example, FIG. 6 illustrates an example machine of a computer system 690 within which a set of instructions, for causing the machine to perform any one or more of the methodologies discussed herein, can be executed. In some embodiments, the computer system 690 can correspond to a host system (e.g., the host system 102 of FIG. 1) that includes, is coupled to, or utilizes a memory system (e.g., the memory system 103 of FIG. 1) or can be used to perform the operations of a controller (e.g., to execute an operating system to perform operations corresponding to the processing element controller 108 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 690 includes a processing device 691, a main memory 693 (e.g., read-only memory (ROM), flash memory, dynamic random-access memory (DRAM) such as synchronous DRAM (SDRAM) or Rambus DRAM (RDRAM), etc.), a static memory 697 (e.g., flash memory, static random-access memory (SRAM), etc.), and a data storage system 698, which communicate with each other via a bus 696. The main memory 693, the static memory 697, and/or the data storage system 698 can include a hybrid memory device (e.g., a hybrid memory device 112 of FIG. 1), as described herein.

The processing device 691 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 691 can also be one or more special-purpose processing devices such as an application specific integrated circuit (ASIC), a field programmable gate array (FPGA), a digital signal processor (DSP), network processor, or the like. The processing device 691 is configured to execute instructions 692 for performing the operations and steps discussed herein. The computer system 690 can further include a network interface device 694 to communicate over the network 695.

The data storage system 698 can include a machine-readable storage medium 699 (also known as a computer-readable medium) on which is stored one or more sets of instructions 692 or software embodying any one or more of the methodologies or functions described herein. The instructions 692 can also reside, completely or at least partially, within the main memory 693 and/or within the processing device 691 during execution thereof by the computer system 690, the main memory 693 and the processing device 691 also constituting machine-readable storage media. The machine-readable storage medium 699, data storage system 698, and/or main memory 693 can correspond to the memory system 103 of FIG. 1.

In one embodiment, the instructions 692 include instructions to implement functionality corresponding to processing element controller (e.g., the processing element controller 108 of FIG. 1). While the machine-readable storage medium 699 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a dynamic random-access memory (DRAM) device configured to store a plurality of weights associated with an artificial neural network;
a static random-access memory (SRAM) device bonded to the DRAM device and configured to:
receive, from the DRAM device through a plurality of through silicon vias (TSVs), the plurality of weights associated with the artificial neural network; and
perform a plurality of operations utilizing the plurality of weights; and
logic configured to perform a summation operation on a result of the plurality of operations.

2. The apparatus of claim 1, wherein TSVs are configured to couple global input output (GIO) lines of the DRAM device to data lines of the SRAM device.

3. The apparatus of claim 1, wherein the SRAM device is further configured to perform the plurality of operations utilizing a number of logic gates.

4. The apparatus of claim 3, wherein the SRAM device is further configured to perform the plurality of operations utilizing an AND gate.

5. The apparatus of claim 1, wherein the SRAM device is further configured to perform the plurality of operations utilizing the plurality of weights and data stored in the DRAM device.

6. The apparatus of claim 5, wherein the data is provided to the SRAM device via the TSVs.

7. The apparatus of claim 5, wherein SRAM device is configured to perform the plurality of operations without a use of sensing circuitry.

8. The apparatus of claim 1, wherein the SRAM device does not include sensing circuitry.

9. A method, comprising:
receiving, at a static random-access memory (SRAM) device, a plurality of weights of an artificial neural network via a plurality of through silicon vias (TSVs) that couple a dynamic random-access memory (DRAM) device to the SRAM device;
storing the plurality of weights in memory cells of the SRAM device;
receiving data at the SRAM device from the DRAM device via the plurality of TSVs;
performing, using logic circuitry of the SRAM device, a plurality of operations utilizing the plurality of weights stored in the SRAM device and the data received from the DRAM device; and
performing a summation operation on a result of the plurality of operations.

10. The method of claim 9, further comprising reading the data from the DRAM device.

11. The method of claim 10, further comprising broadcasting the data read from the DRAM device to the SRAM device utilizing data lines of the SRAM device.

12. The method of claim 11, wherein performing the plurality of operations includes performing a plurality of AND operations utilizing the plurality of weights and the data.

13. The method of claim 11, wherein storing the plurality of weights further includes firing a plurality of select lines to cause the plurality of weights to be transferred from the data lines to memory cells of the SRAM device.

14. The method of claim 11, further comprising updating the plurality of weights by firing a plurality of select lines of the SRAM device to transfer the plurality of weights from the data lines to the memory cells of the SRAM device.

15. An apparatus, comprising:
a dynamic random-access memory (DRAM) device configured to store data;
a static random-access memory (SRAM) device configured to store a plurality of weights of an artificial neural network, wherein the SRAM device is bonded to the DRAM device; and
wherein the SRAM device is further configured to:
receive the data via a plurality of through silicon vias (TSVs) that couple the DRAM device to the SRAM device;
perform a first plurality of operations utilizing the plurality of weights stored in the SRAM device and the data received from the DRAM device;
logic configured to perform a summation operation on a result of the first plurality of operations; and
shift and accumulate circuitry configured to perform a second plurality of operations using a result of the summation operation, wherein the first plurality of operations, the summation operation, and the second plurality of operations are performed to implement an artificial neural network (ANN).

16. The apparatus of claim 15, wherein the shift and accumulate circuitry is configured to perform the second plurality of operations to implement a convolution neural network (CNN).

17. The apparatus of claim 15, wherein the SRAM device includes a plurality of processing elements, wherein each of the plurality of processing element includes a plurality of memory cells configured to store one of the plurality of weights.

18. The apparatus of claim 17, wherein each of the processing elements includes select circuitry configured to couple the data lines of the SRAM device to GUT lines of the SRAM device to cause the plurality of weights to be stored in the plurality of processing elements.

19. The apparatus of claim 18, wherein the plurality of memory cells is directly coupled to the GUT lines and indirectly coupled to the data lines via the select circuitry.

20. The apparatus of claim 17, wherein the SRAM device is further configured to perform the first plurality of operations by concurrently transferring the plurality of weights via the GUT lines and the data via the data lines to AND gates of the plurality of processing elements.
